(19) United States
(12) Patent Application Publication
(10) Pub. No.: US 2010/0044770 A1
(43) Pub. Date: Feb. 25, 2010

(54) SEMICONDUCTOR DEVICE AND METHOD OF FABRICATING THE SAME

(75) Inventor: Nam-Jae LEE, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Icheon-si (KR)

(21) Appl. No.: 12/403,622

(22) Filed: Mar. 13, 2009

(30) Foreign Application Priority Data
Aug. 22, 2008 (KR) 10-2008-0082416

(51) Int. Cl. H01L 29/788; H01L 21/28; H01L 21/283

(52) U.S. Cl. 257/315; 438/594; 438/586; 438/682; 257/751; 257/E21.209; 257/E21.159; 257/E29.3

(57) ABSTRACT

A method for fabricating a semiconductor device includes forming an insulation layer over a substrate, forming a diffusion barrier for preventing metal diffusion over the insulation layer, forming a gate electrode layer over the diffusion barrier, forming a metal layer over the gate electrode layer, and performing a thermal treatment process on the substrate structure to form a metal silicide layer having a uniform thickness.

### CROSS-REFERENCE TO RELATED APPLICATIONS

The present application claims priority of Korean patent application number 10-2008-0082416, filed on Aug. 22, 2008, which is incorporated herein by reference in its entirety.

### BACKGROUND

The disclosure relates to a semiconductor device and a method for fabricating the same, and more particularly, to a semiconductor device including a metal silicide layer and a method for fabricating the same.

Recently, higher integration of semiconductor devices has caused the dimensions to decrease. Thus, resistance of gate electrodes increased, deteriorating semiconductor device characteristics. Accordingly, a typical method may form a gate electrode so as to include a metal silicide layer to reduce the resistance thereof.

FIGS. 1A and 1B are cross-sectional views describing a method for forming a typical metal silicide layer in a nonvolatile memory device.

Referring to FIG. 1A, a tunnel insulation layer 110 is formed over a substrate 100. The tunnel insulation layer 110 is formed as an energy barrier layer for tunneling of electric charges. The tunnel insulation layer 110 includes an oxide-based layer.

A floating gate electrode layer 120 is formed over the tunnel insulation layer 110. The floating gate electrode stores data by storing or erasing electric charges. The floating gate electrode layer 120 includes a polysilicon layer.

A dielectric layer 130 is formed over the floating gate electrode layer 120. The dielectric layer 130 is formed to prevent electric charges from moving to an upper portion of a control gate after passing the floating gate electrode.

A control gate electrode layer 140 is formed over the dielectric layer 130. A metal layer 150 is formed over the control gate electrode layer 140. Reference denotation W1 represents the thickness of the control gate electrode layer 140.

Referring to FIG. 1B, a thermal treatment process is performed on the substrate structure to react the control gate electrode layer 140 with the metal layer 150. Thus, a metal silicide layer 140A is formed. Non-reacted portions of the metal layer 150 during the thermal treatment process are removed. Reference numeral 140B represents a remaining control gate electrode layer 140B.

According to this particular method, resistance values of the control gate electrode become uneven because the thickness of the metal silicide layer 140A, represented with reference denotation W2, is not even. In such a case, resistance values of gate lines become uneven, causing parasitic capacitance values between word lines to become uneven.

In particular, because the metal diffusion level of the metal layer 150 may not be controlled, if the metal is diffused to the dielectric layer 130, as denoted with reference denotation ‘A’ in FIG. 1B, the dielectric layer 130 may be damaged to undermine reliability of the nonvolatile memory device. In the above method, the thickness W1 of the control gate electrode layer 140 is increased to prevent damaging the dielectric layer 130. However, the increased thickness of the control gate electrode layer 140 may deteriorate integration of the memory device.

### SUMMARY

One or more embodiments are directed to provide a semiconductor device and a method for fabricating the same, the semiconductor device including a gate electrode which comprises a metal silicide layer having an even thickness.

In accordance with one embodiment, there is provided a method for fabricating a semiconductor device, which includes: forming an insulation layer over a substrate; forming a diffusion barrier for preventing metal diffusion over the insulation layer; forming a gate electrode layer over the diffusion barrier; forming a metal layer over the gate electrode layer; and performing a thermal treatment process on the substrate structure to form a metal silicide layer having a uniform thickness.

In accordance with another embodiment, there is provided a semiconductor device, which includes: an insulation layer formed over a substrate; and a gate electrode formed over the insulation layer, the gate electrode including a diffusion barrier for preventing metal diffusion and a metal silicide layer.

### BRIEF DESCRIPTION OF THE DRAWINGS

Various embodiments are illustrated by way of example, and not by limitation, in the figures of the accompanying drawings.

FIGS. 1A and 1B illustrate cross-sectional views of a typical method for fabricating a semiconductor device.

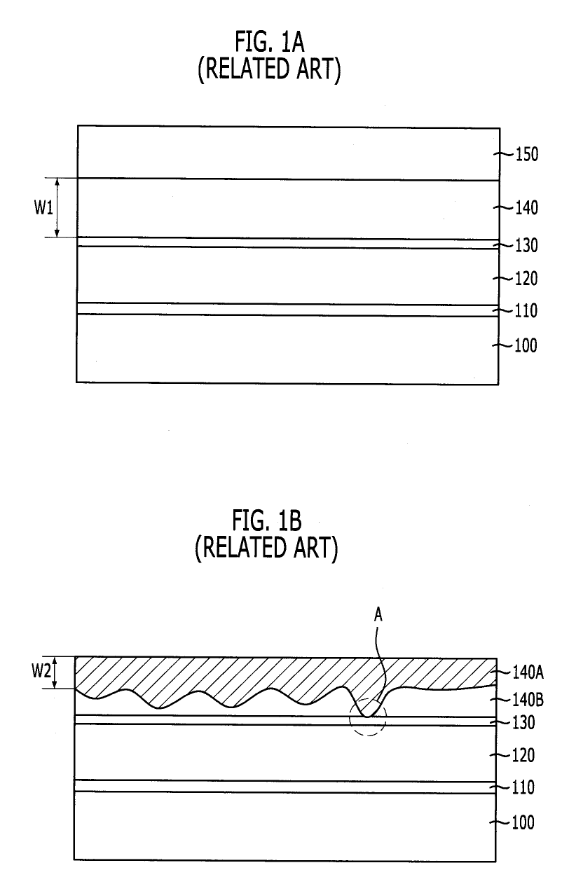

FIGS. 2A and 2B illustrate cross-sectional views of a method for fabricating a semiconductor device in accordance with a first embodiment.

FIGS. 3A and 3B illustrate cross-sectional views of a method for fabricating a semiconductor device in accordance with a second embodiment.

### DESCRIPTION OF EMBODIMENTS

Other objects and advantages of the present disclosure can be understood by the following description, and become apparent with reference to the disclosed embodiments. Well-known elements may not be described in this patent specification. The same reference numerals are given to the same elements although they appear in different drawings.

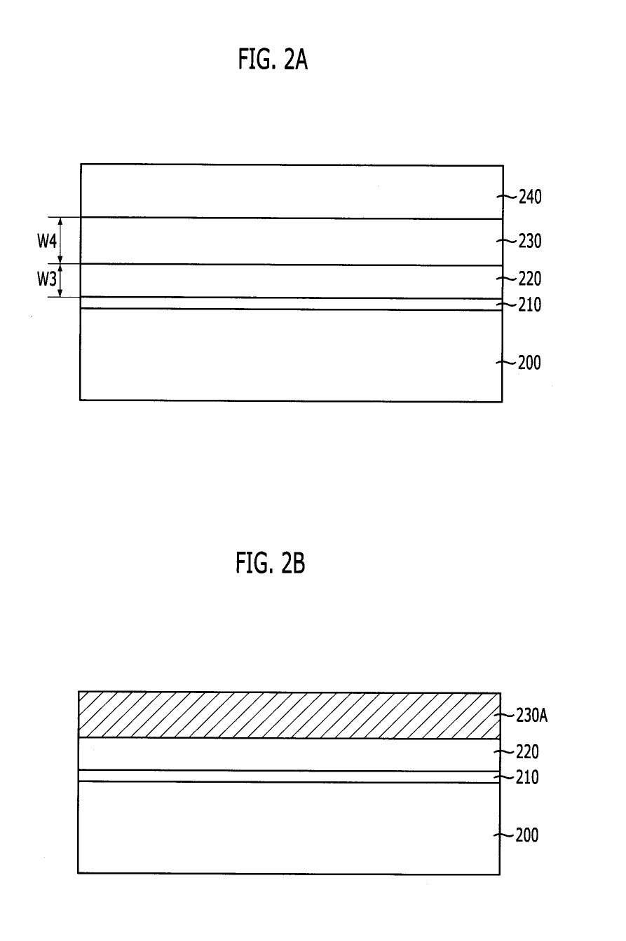

FIGS. 2A and 2B are cross-sectional views describing a method for forming a metal silicide layer in accordance with a first embodiment. Referring to FIG. 2A, an insulation layer 210 is formed over a substrate 200. For instance, the insulation layer 210 includes an oxide-based layer or a dielectric layer.

A diffusion barrier 220 for preventing metal diffusion is formed over the insulation layer 210. The diffusion barrier 220 is formed to control the thickness of a metal silicide layer and to prevent metal included in a metal layer from diffusing into the insulation layer 210 during a subsequent thermal treatment process.

For instance, the diffusion barrier 220 includes a material having a property which is different from polysilicon. In particular, the diffusion barrier 220 may include a tungsten silicide (WSi) layer which has a different material property from polysilicon and has a stable hexagonal structure. Also, the diffusion barrier 220 may be formed to a thickness, as denoted with reference denotation W3, ranging from approximately 100 Å to approximately 1,000 Å.

A gate electrode layer 230 is formed over the diffusion barrier 220. For instance, the gate electrode layer 230 includes a polysilicon layer. According to the method for forming a metal silicide layer shown in the first embodiment, the gate electrode layer 230 may be formed to a thickness smaller than that of a typical method because the metal is prevented from diffusing into the insulation layer 210 during the subsequent thermal treatment process. The reduced thickness of the gate electrode layer 230 is denoted with reference denotation W4.

A metal layer 240 is formed over the gate electrode layer 230. For instance, the metal layer 240 includes cobalt (Co) or nickel (Ni).

Referring to FIG. 2B, a thermal treatment process is performed on the substrate structure to react the gate electrode layer 230 with the metal layer 240. Thus, a metal silicide layer 230A is formed. For instance, the metal silicide layer 230A includes cobalt silicide (CoSi₂) or nickel silicide (NiSi). Non-reacted portions of the metal layer 240 during the thermal treatment process are removed.

During the thermal treatment process for forming the metal silicide layer 230A, metal included in the metal layer 240 is diffused into the gate electrode layer 230 to form the metal silicide layer 230A.

At this time, the extent of metal diffusion is controlled by the diffusion barrier 220 formed below the gate electrode layer 230. In other words, the metal may be diffused for as much as the thickness of the gate electrode layer 230, that is, for as much as W4. The metal may not be diffused any further because the diffusion barrier 220 is formed below the gate electrode layer 230.

Therefore, it is possible to reduce the thickness W4 of the gate electrode layer 230 to a level smaller than the typical method because damages of the insulation layer 210 by metal diffusion may be prevented. Furthermore, a gate electrode including a metal silicide layer of an even thickness may be formed and thus the gate electrode has uniform resistance values.

Although not illustrated, the metal silicide layer 230A, the diffusion barrier 220, and the insulation layer 210 are selectively etched to form a gate pattern. Thus, the gate electrode including portions of the diffusion barrier 220 and the metal silicide layer 230A having an even thickness is formed.

When forming the diffusion barrier 220 and the gate electrode layer 230, a first gate electrode layer may be formed before forming the diffusion barrier 220 and a second gate electrode layer may be formed over the diffusion barrier 220. That is, the diffusion barrier 220 may be formed in a manner that the diffusion barrier 220 is formed between two gate electrode layers. In this case, during the thermal treatment process for forming the metal silicide layer, metal included in the metal layer 240 may be diffused to the degree of the thickness of the second gate electrode layer. The metal may not be diffused any further because of the diffusion barrier 220 formed below the second gate electrode layer. Thus, a gate electrode including a first gate electrode layer, a diffusion barrier, and a second gate electrode layer may be formed.

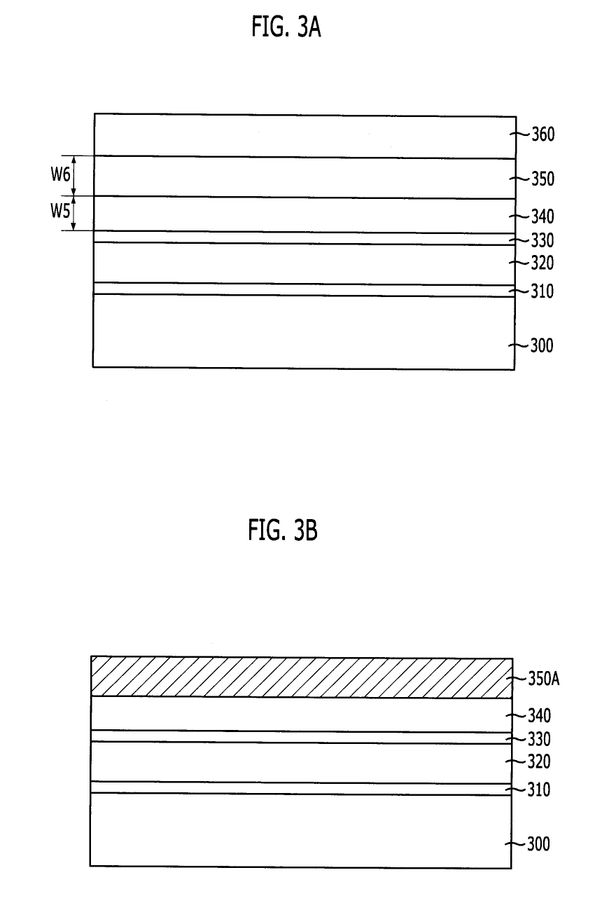

FIGS. 3A and 3B illustrate cross-sectional views of a method for forming a metal silicide layer in a floating gate type nonvolatile memory device in accordance with a second embodiment.

Referring to FIG. 3A, a tunnel insulation layer 310 is formed over a substrate 300. The tunnel insulation layer 310 is formed as an energy barrier layer for tunneling of electric charges. For instance, the tunnel insulation layer 310 includes an oxide-based layer.

A floating gate electrode layer 320 is formed over the tunnel insulation layer 310. The floating gate electrode layer 320 is formed to form a floating gate electrode in a subsequent process. The floating gate electrode stores data by storing or erasing electric charges. For instance, the floating gate electrode layer 320 includes a polysilicon layer.

A dielectric layer 330 is formed over the floating gate electrode layer 320. The dielectric layer 330 is formed to prevent electric charges from moving to an upper portion of a control gate after passing the floating gate electrode. For instance, the dielectric layer 330 includes an aluminum oxide (Al₂O₃) layer.

Although not illustrated, a polysilicon layer may be formed over the dielectric layer 330. The polysilicon layer is formed as a protection layer to prevent damages of the dielectric layer 330 during a formation process of an oxide/nitride/oxide (ONO) contact for a normal operation for transistors such as a select transistor.

A diffusion barrier 340 is formed over the dielectric layer 330 or the polysilicon layer. The diffusion barrier 340 is formed to prevent metal included in a metal layer from diffusing into the dielectric layer 330 and even into the tunnel insulation layer 310 during a subsequent thermal treatment process for forming a metal silicide layer.

For instance, the diffusion barrier 340 includes a material having a different material property from the polysilicon layer. In particular, the diffusion barrier 340 may include a tungsten silicide (WSi) layer which has a different material property from polysilicon and has a stable hexagonal structure. Also, the diffusion barrier 340 may be formed to a thickness, as denoted with reference denotation W5, ranging from approximately 100 Å to approximately 1,000 Å.

A control gate electrode layer 350 is formed over the diffusion barrier 340. According to the method for forming a metal silicide layer according to the second embodiment, the control gate electrode layer 350 may be formed to a thickness smaller than normal because the metal is prevented from diffusing into the dielectric layer 330 or the tunnel insulation layer 310 during the subsequent thermal treatment process. The reduced thickness of the control gate electrode layer 350 is denoted by W6.

After the control gate electrode layer 350 is formed over the diffusion barrier 340, a metal layer 360 is formed over the control gate electrode layer 350. For instance, the metal layer 360 includes cobalt (Co) or nickel (Ni).

Referring to FIG. 3B, a thermal treatment process is performed on the substrate structure to react the control gate electrode layer 350 with the metal layer 360. Thus, a metal silicide layer 350A is formed. For instance, the metal silicide layer 350A includes cobalt silicide (CoSi₂) or nickel silicide (NiSi). Non-reacted portions of the metal layer 360 during the thermal treatment process are removed.

During the thermal treatment process for forming the metal silicide layer 350A, metal included in the metal layer 360 is diffused into the control gate electrode layer 350 to form the metal silicide layer 350A. The depth of the metal diffusion is controlled by the diffusion barrier 340 formed below the control gate electrode layer 350. That is, the diffusion barrier 340 prevents the metal from diffusing into the dielectric layer 330 and even to the tunnel insulation layer 310. Thus, the thickness W6 of the control gate electrode layer 350 may be reduced to a level smaller than that typically used and deterioration of device reliability may be prevented due to damage to the dielectric layer 330. Because a gate electrode including a metal silicide layer having a uniform thickness is formed, the gate electrode obtains uniform resistance values.

Although not illustrated, the metal silicide layer 350A, the diffusion barrier 340, the dielectric layer 330, and the floating gate electrode layer 320 are selectively etched to form a gate pattern. Thus, the gate pattern including the diffusion barrier 340 and the metal silicide layer 350A having a uniform thickness is formed.

Although the embodiments described a method for fabricating a floating gate type nonvolatile memory device which implants or discharges electric charges to a floating gate electrode for convenience of description, the underlying concept is not limited to the above described embodiments, and may be applied to a charge trap type nonvolatile memory device which implants or discharges electric charges to a charge trap layer. For instance, the charge trap type nonvolatile memory device includes a tunnel insulation layer formed over a substrate, a charge trap layer, a dielectric layer, and control gate electrode. The charge trap layer may include a nitride-based layer.

Embodiments relate to a semiconductor device and a method for fabricating the same. In the embodiments, the depth of diffusion for metal included in a metal layer may be controlled by a diffusion barrier when forming a metal silicide layer using a thermal treatment process. Thus, a metal silicide layer having a uniform thickness may be formed and a gate electrode may have uniform resistance values. Also, the thickness of a polysilicon layer may be reduced to a level smaller than that of a typical method because the metal is prevented from diffusing into a dielectric layer below a gate electrode layer. In particular, deterioration of reliability caused by damages of a dielectric layer may be prevented when forming a nonvolatile memory device.

While description has been made with respect to the specific embodiments, it will be apparent to those skilled in the art that various changes and modifications may be made without departing from the spirit and scope defined in the following claims.

What is claimed is:

1. A method for fabricating a semiconductor device, comprising:
forming an insulation layer over a substrate;
forming a diffusion barrier for preventing metal diffusion over the insulation layer;
forming a gate electrode layer over the diffusion barrier;
forming a metal layer over the gate electrode layer; and
performing a thermal treatment process on the substrate structure to for a metal silicide layer having a uniform thickness.

2. The method of claim 1, wherein the diffusion barrier is formed of a material having a different material property from the gate electrode layer.

3. The method of claim 2, wherein the diffusion barrier comprises a tungsten silicide layer.

4. The method of claim 1, wherein the diffusion barrier is formed to a thickness ranging from approximately 100 Å to approximately 1,000 Å.

5. The method of claim 1, wherein the gate electrode layer is a polysilicon layer.

6. The method of claim 1, wherein the metal layer comprises cobalt (Co) or nickel (Ni).

7. The method of claim 1, wherein the metal silicide layer comprises one of cobalt silicide (CoSi₂) and nickel silicide (NiSi).

8. The method of claim 1, further comprising, after performing the thermal treatment process on the substrate structure to form the metal silicide layer, removing non-reacted portions of the metal layer during the thermal treatment process.

9. The method of claim 1, further comprising, before forming the diffusion barrier, forming another gate electrode layer over the insulation layer.

10. The method of claim 1, wherein the insulation layer is a dielectric layer, and the method further comprising, before forming the insulation layer:
forming a tunnel insulation layer over the substrate; and
forming a floating gate electrode layer over the tunnel insulation layer.

11. The method of claim 1, wherein the insulation layer is a dielectric layer, and the method further comprising, before forming the insulation layer:
forming a tunnel insulation layer over the substrate; and
forming a charge trap layer over the tunnel insulation layer.

12. A semiconductor device, comprising:
an insulation layer formed over a substrate; and
a gate electrode formed over the insulation layer, the gate electrode including a diffusion barrier for preventing metal diffusion and a metal silicide layer.

13. The semiconductor device of claim 12, wherein the diffusion barrier comprises a material having a different material property from a polysilicon layer.

14. The semiconductor device of claim 13, wherein the diffusion barrier is a tungsten silicide layer.

15. The semiconductor device of claim 12, wherein the diffusion barrier is formed to a thickness ranging from approximately 100 Å to approximately 1,000 Å.

16. The semiconductor device of claim 12, wherein the metal silicide layer comprises one of cobalt silicide (CoSi₂) and nickel silicide (NiSi).

17. The semiconductor device of claim 12, further comprising a polysilicon layer formed between the insulation layer and the diffusion barrier.

18. The semiconductor device of claim 12, wherein the insulation layer is a dielectric layer, and which further comprises:
a tunnel insulation layer formed over the substrate; and
a floating gate electrode layer formed between the tunnel insulation layer and the insulation layer.

19. The semiconductor device of claim 12, wherein the insulation layer is a dielectric layer, and which further comprises:
a tunnel insulation layer formed over the substrate; and
a charge trap layer formed between the tunnel insulation layer and the insulation layer.
